(19) United States
(12) Patent Application Publication
(10) Pub. No.: US 2020/0105720 A1
(43) Pub. Date: Apr. 2, 2020

(54) STACKED SEMICONDUCTOR DEVICES AND METHOD OF MANUFACTURING THE SAME

(71) Applicant: GLOBALFOUNDRIES INC., Grand Cayman (KY)

(72) Inventors: Qin Yuan, Poughquag, NY (US); Jorge Lubguban, Danbury, CT (US)

(21) Appl. No.: 16/149,150

(22) Filed: Oct. 2, 2018

(51) Int. Cl. H01L 25/065; H01L 23/532; H01L 23/00; H01L 21/768; H01L 21/02

(52) U.S. Cl. CPC H01L 25/0657; H01L 23/53238; H01L 24/09; H01L 21/02532; H01L 21/02554; H01L 21/0254; H01L 21/76841

(57) ABSTRACT

The present disclosure relates to stacked semiconductor devices and, more particularly, to stacked integrated circuit (IC) chips or wafers and to their methods of manufacturing. The stacked semiconductor device of the present disclosure comprises a first chip having a surface, a hydrogen permeable barrier layer on the surface of the first chip, and a second chip bonded to the first chip. The hydrogen permeable barrier layer is positioned between the first chip and the second chip.

### FIELD OF THE INVENTION

The present disclosure relates to stacked semiconductor devices and, more particularly, to stacked integrated circuit (IC) chips or wafers and to their method of manufacturing.

### BACKGROUND

Semiconductor packaging processes may include formation of a three-dimensional integrated circuit (3D IC) by stacking semiconductor wafers or IC chips and interconnecting them vertically. Stacked semiconductor devices generally contain two or more wafers. A planar, smooth and clean wafer surface is usually required for wafer bonding to prevent defectives in the stacked semiconductor devices. The materials and processing steps used in forming the semiconductor devices can affect the planarity and smoothness of the wafer surface.

Dielectric materials are commonly added to semiconductor devices during fabrication processes. These dielectric materials may be deposited as a film overlying the surface of a wafer or as insulating layers between metal interconnects within a wafer. For example, silicon nitride may be used as a dielectric etch stop layer in a wafer. Outgassing from dielectric materials in 3D packaging during thermal treatment is detrimental and can cause formation of voids or air pockets between bonded wafer interfaces. For example, hydrogen gas may be released from silicon nitride materials. If the released hydrogen gas is trapped beneath the silicon nitride dielectric material, then voids/air pockets will show up post thermal treatment.

Formation of air pockets at the surface of a wafer is a significant problem in semiconductor device fabrication, as it prevents complete bonding of stacked semiconductor devices. Consequently, wafers containing air pockets may need to be scrapped, which leads to production loss, lost revenue and wastage of materials.

### SUMMARY

In one aspect of the present disclosure, there is provided a stacked semiconductor device including a first chip having a surface, a hydrogen permeable barrier layer on the surface of the first chip, and a second chip bonded to the first chip. The hydrogen permeable barrier layer is positioned between the first chip and the second chip. The hydrogen permeable barrier includes silicon oxynitride.

In another aspect of the present disclosure, there is provided a method of manufacturing a stacked semiconductor device including forming a hydrogen permeable barrier layer on a surface of a first wafer, and bonding the first wafer with a second wafer. The hydrogen permeable barrier layer is positioned between the first wafer and the second wafer.

Advantageously, the presence of silicon oxynitride at the surface of a wafer is found to prevent the formation of air pockets at the bonded wafer surface post thermal treatment. Gases released from dielectric materials may permeate through the molecular structure of silicon oxynitride. More advantageously, silicon oxynitride can function as a protective film to prevent moisture and contamination from entering into the wafer as well as an etch stop layer during the etching process.

### BRIEF DESCRIPTION OF THE DRAWINGS

The present disclosure is described in the detailed description which follows, in reference to the noted plurality of drawings by way of non-limiting examples of exemplary embodiments of the present disclosure.

For simplicity and clarity of illustration, the drawings illustrate the general manner of construction, and certain descriptions and details of well-known features and techniques may be omitted to avoid unnecessarily obscuring the discussion of the described embodiments of the device. Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

FIGS. 1-5 are schematic cross-sectional views of a first wafer at successive stages of manufacturing a stacked semiconductor device as described herein.

FIG. 6 is a schematic diagram depicting cross-sectional views of a first wafer and a second wafer during the bonding stage of the stacked semiconductor device manufacturing processes as described herein.

FIGS. 7A-7B are schematic cross-sectional views of stacked semiconductor devices as described herein.

FIG. 8 is a schematic diagram illustrating the mechanism in which hydrogen gases may permeate through the silicon oxynitride layer of the stacked semiconductor device.

### DETAILED DESCRIPTION

The present disclosure relates to stacked semiconductor devices and, more particularly, to stacked IC chips or wafers and their method of manufacturing. As used herein, the term “stacked semiconductor device” refers to semiconductor wafers or chips that are stacked on top of each other by chip-to-chip bonding, chip-to-wafer bonding or wafer-to-wafer bonding. The stacked semiconductor device of the present disclosure includes a first chip having a surface, a hydrogen permeable barrier layer on the surface of the first chip, and a second chip bonded to the first chip. As used herein, the term “hydrogen permeable” refers to a material that allows hydrogen gas to permeate or diffuse through. The hydrogen permeable barrier layer is sandwiched between the first chip and the second chip. In a preferred embodiment, the hydrogen permeable barrier layer includes silicon oxynitride. The hydrogen permeable barrier layer includes a first silicon oxynitride layer and a second silicon oxynitride layer. A first oxide layer is disposed on the hydrogen permeable barrier layer. The first oxide layer is bonded to a second oxide layer on the second chip. The second silicon oxynitride layer may be sandwiched between the first oxide layer and the first silicon oxynitride layer. As used herein, the term “sandwiched” broadly refers to one item (center item) placed, disposed or positioned between two other items (outer items), but the center item does not necessarily touch the outer items.

The present disclosure also relates to a method of manufacturing a stacked semiconductor device as described herein. The present method includes forming a hydrogen permeable barrier layer on a surface of a first wafer, and bonding a second wafer with the first wafer. The hydrogen permeable barrier layer is sandwiched between the first wafer and the second wafer. Formation of the hydrogen permeable barrier layer includes forming, for example, a first silicon oxynitride layer on the surface of the first wafer, planarizing the first silicon oxynitride layer, and forming, for example, a second silicon oxynitride layer on the first silicon oxynitride layer. Here, silicon oxynitride is used only as a non-limiting example of materials and other hydrogen permeable materials (e.g., silicon oxycarbonitride) may be used as well. The method also includes forming a first oxide layer on the second silicon oxynitride layer, and forming a second oxide layer on a surface of the second wafer. Bonding the first and second wafers includes bonding the first oxide layer and the second oxide layer. The bonding may be performed directly by elevated temperature annealing or by plasma enhanced low temperature bonding followed by thermal treatment. The bonding of the first oxide layer and the second oxide layer further includes treating the first and second oxide layers with plasma and water before annealing.

The wafers described herein may be manufactured in a number of ways using a number of different tools, and are formed with dimensions in the micrometer and nanometer scale per their intended design. Generally, methodologies and tools employed to manufacture the wafers have been adopted from known semiconductor technologies. For example, wafers are manufactured by building IC structures (e.g., transistors, capacitors, etc.) on a semiconductor substrate such as silicon.

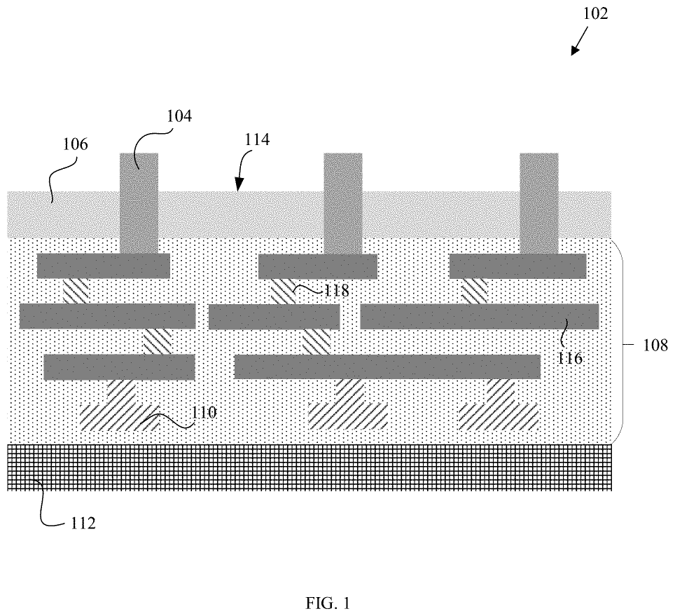

Referring to FIG. 1, an embodiment of a first wafer 102 is depicted. The first wafer 102 may be fabricated by known semiconductor processes. The first wafer 102 has a first wafer surface 114, a first inter-metal dielectric layer 108, and a first substrate 106. The first wafer 102 may additionally include a sacrificial silicon layer 112. The first substrate 106 may be formed using a suitable semiconductor material. In a preferred embodiment, the first substrate 106 is formed using silicon. The first substrate 106 includes a plurality of through silicon vias (TSVs) 104. The TSVs 104 may be formed using any suitable electrical conductors. In a preferred embodiment, the TSVs 104 are made of copper. The TSVs 104 extend through the first substrate 106 and are exposed at the first wafer surface 114. The first inter-metal dielectric layer 108 includes metal lines 116, interconnect vias 118, and aluminum pads 110. The metal lines 116 and interconnect vias 118 may be formed using any suitable electrical conductors. In a preferred embodiment, the metal lines 116 and interconnect vias 118 are made of copper. The first substrate 106 may include front end of line (FEOL) components (e.g., transistors, capacitors, etc.). The first inter-metal dielectric layer 108 may include various dielectric materials which are suitable for back end of line (BEOL) processes.

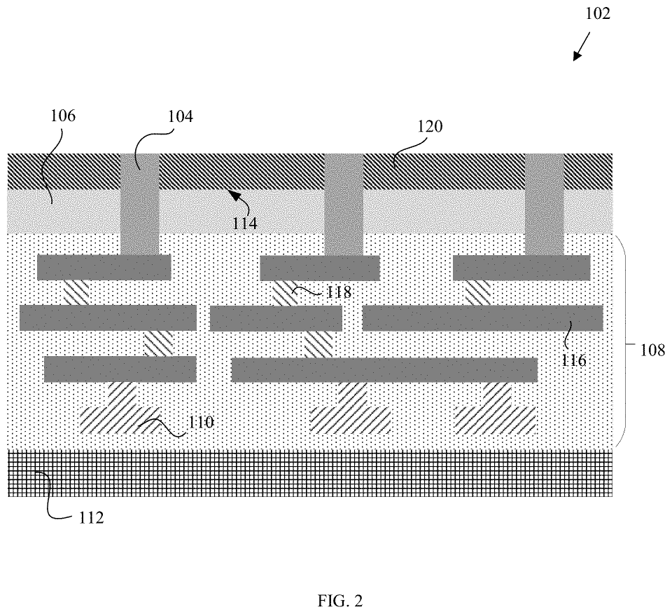

With reference to FIG. 2 in which like reference numerals refer to like features in FIG. 1 and at a subsequent fabrication stage, a first hydrogen permeable layer, such as silicon oxynitride layer, 120 is formed on the first wafer surface 114 although materials other than silicon oxynitride may be used as well. In a preferred embodiment, chemical mechanical planarization (CMP) is performed to ensure that the first silicon oxynitride layer 120 is planar with the TSVs 104. The first silicon oxynitride may be formed by any deposition techniques, such as chemical vapor deposition (CVD), atomic layer deposition (ALD), thin film deposition process, or electro-less deposition. In one preferred embodiment, the first silicon oxynitride layer 120 is deposited using CVD.

As used herein, “silicon oxynitride” refers to a compound having a chemical formula of Siₓ O_{y} N, wherein x, y, and z are in stoichiometric ratio. The composition of oxygen and nitrogen in silicon oxynitride is dependent on the amount and type of precursors used in the deposition process. In one embodiment, the precursors include silane, nitrous oxide, ammonia, and nitrogen. The refractive index of silicon oxynitride can be an indicator of the amount of oxygen and nitrogen in silicon oxynitride. The refractive index of silicon oxynitride may vary between the refractive indices of silicon dioxide and silicon nitride. The first silicon oxynitride layer may have a refractive index in the range of about 1.7 to about 2.0. The deposition rate of the first silicon oxynitride layer 120 may be in the range of about 35 Å/s to about 55 Å/s. The thickness of the first silicon oxynitride layer 120 may be about 0.1 μm to about 3 μm.

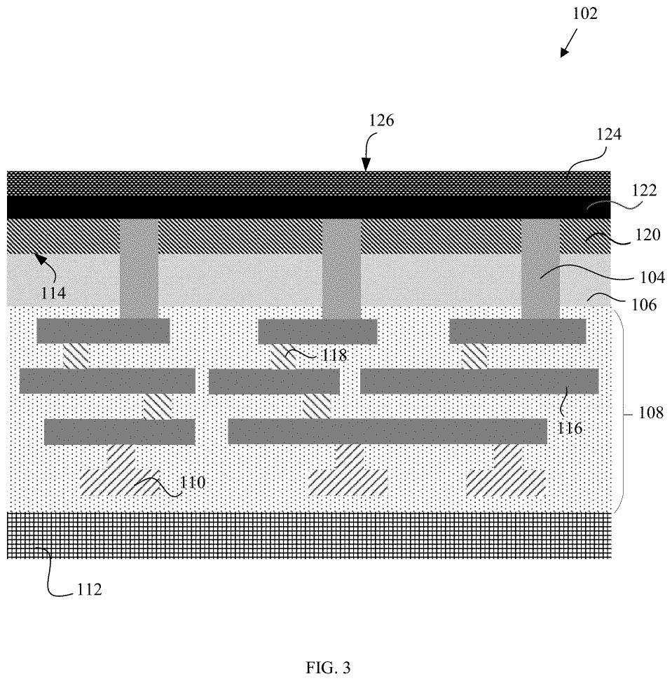

With reference to FIG. 3 in which like reference numerals refer to like features in FIG. 2 and at a subsequent fabrication stage, a second hydrogen permeable layer, such as silicon oxynitride layer, 122 is formed on the first silicon oxynitride layer 120 although other hydrogen permeable material may be used as well. The first silicon oxynitride layer 120 and the second silicon oxynitride layer 122 constitute a hydrogen permeable barrier layer. The second silicon oxynitride layer 122 may have a refractive index in the range of about 1.7 to about 2.0. The deposition rate of the second silicon oxynitride layer 122 may be in the range of about 35 Å/s to about 55 Å/s. The thickness of the second silicon oxynitride layer 122 may be about 0.09 μm to about 2 μm, or about 1000 Å.

A first oxide layer 124 is formed over the second silicon oxynitride layer 122. The first oxide layer 124 has a first oxide surface 126. The thickness of the first oxide layer may be about 0.1 μm to about 1 μm. The first oxide layer 124 may be formed using any deposition techniques, such as CVD, ALD, thin film deposition process, or electro-less deposition. In one embodiment, the first oxide layer 124 is deposited using CVD. In one embodiment, the precursors of the deposition process are silane and oxygen. The deposition rate of the first oxide layer may be about 10 Å/s to about 70 Å/s.

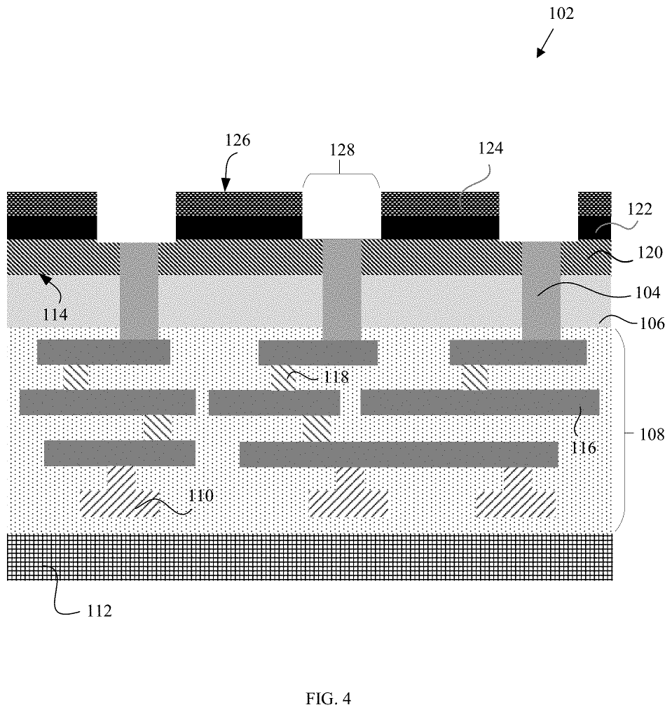

With reference to FIG. 4 in which like reference numerals refer to like features in FIG. 3 and at a subsequent fabrication stage, a damascene process is performed on the first wafer 102. A lithographic process and a reactive ion etching (RIE) process is performed on the first oxide layer 124 and second silicon oxynitride layer 122 to form trenches 128 positioned over the first silicon oxynitride layer 120. Advantageously, the second silicon oxynitride layer 122 functions as an etch stop layer in which the etching process stops upon detection of the second silicon oxynitride layer 122. In one embodiment, over etching may continue after detection of the second silicon oxynitride layer 122. Over etching is performed to remove a portion of the second silicon oxynitride layer 122 to reveal the TSVs 104.

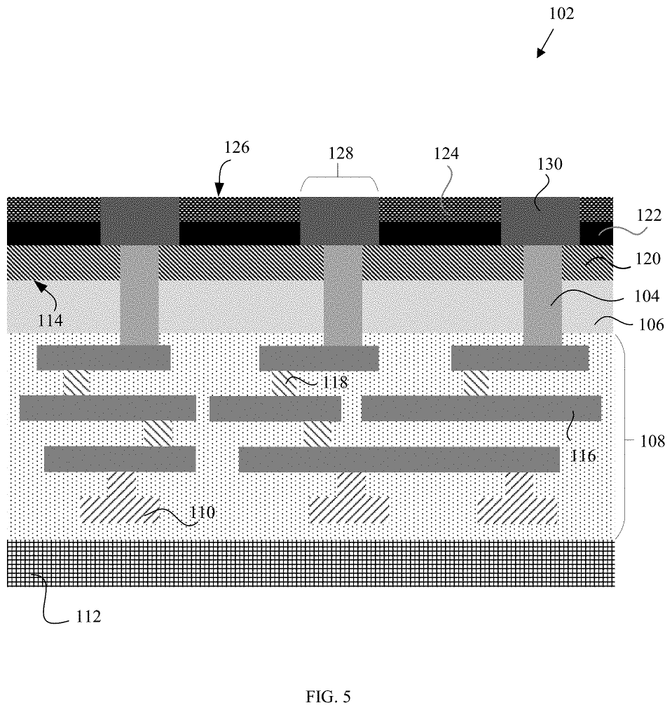

With reference to FIG. 5 in which like reference numerals refer to like features in FIG. 4 and at a subsequent fabrication stage, copper pads 130 are formed in the trenches 128. The copper pads 130 are formed by first depositing a copper seed layer followed by electroplating the remaining copper materials. CMP process is subsequently performed to ensure the copper pads 130 are planar with the first oxide layer 124.

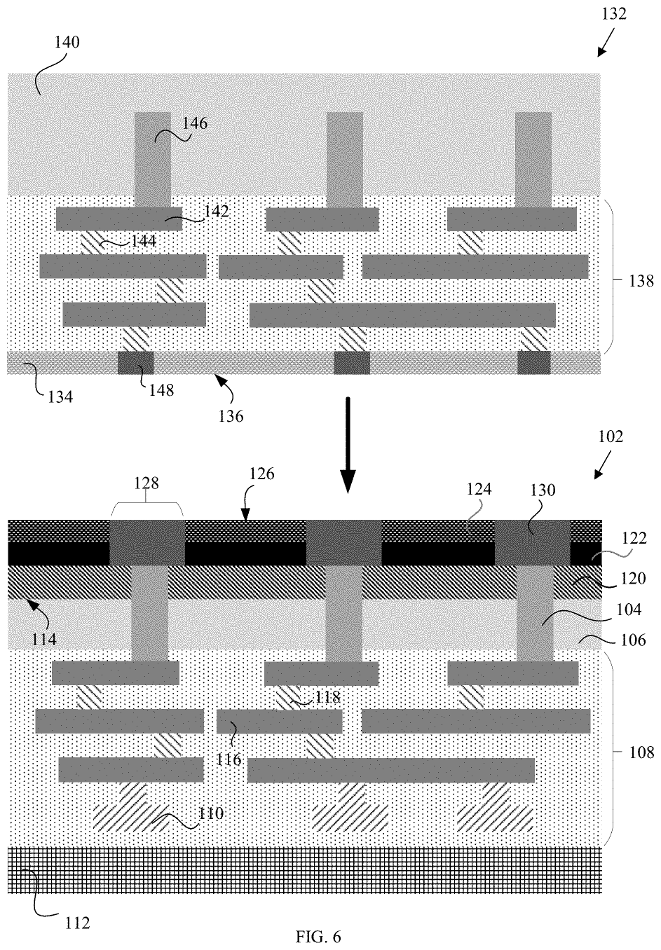

With reference to FIG. 6 in which like reference numerals refer to like features in FIG. 5 and at a subsequent fabrication stage, an embodiment of a second wafer 132 is brought into contact with the first wafer 102. The second wafer 132 has a second substrate 140 and a second inter-metal dielectric layer 138. The second substrate 140 may be formed using any suitable semiconductor materials. In a preferred embodiment, the second substrate 140 is formed using silicon. The second substrate 140 includes a plurality of TSVs 146. The TSVs 146 may be formed using any suitable electrical conductors. In a preferred embodiment, the TSVs 146 are made of copper. The second substrate 140 may include FEOL components (e.g., transistors, capacitors, etc.).

The second inter-metal dielectric layer 138 includes metal lines 142, interconnect vias 144, and a second oxide layer 134. The second inter-metal dielectric layer 138 may also include various dielectric materials, which are suitable for BEOL processes. In a preferred embodiment, the second oxide layer 134 is formed on an opposing surface of the second wafer 132. The second oxide layer 134 may include silicon dioxide, or an organosilicon compound. The organosilicon compound may be any organometallic compound containing carbon-silicon bonds. In one embodiment, the organosilicon compound is tetraethyl orthosilicate. The second oxide layer 134 may be formed using any deposition techniques, such as CVD, ALD, thin film deposition process, or electro-less deposition. In one embodiment, the second oxide layer 134 is deposited using CVD. The second oxide layer 134 is planar with copper pads 148. The metal lines 142 and interconnect vias 144 may be formed using any suitable electrical conductors. In a preferred embodiment, the metal lines 142 and interconnect vias 144 are made of copper.

The second oxide layer 134 has a second oxide surface 136. During bonding of the first oxide layer 124 and the second oxide layer 134, the first oxide surface 126 is in direct contact with the second oxide surface 136. Additionally, the copper pads 130 of the first wafer 102 and the copper pads 148 of the second wafer 132 are in direct contact with each other. In a preferred embodiment, the bonding may be performed by a plasma enhanced low temperature bonding followed by an annealing process. The annealing may occur at a temperature between about 260° C. and about 400° C. During annealing, siloxane linkages (e.g. Si—O—Si) may be formed between the first oxide layer 124 and the second oxide layer 134.

In a preferred embodiment, prior to the bonding step, the first oxide surface 126 and the second oxide surface 136 are treated with plasma and water. The plasma may be nitrogen plasma. Advantageously, the treatment of plasma and water may cause the first oxide surface 126 and the second oxide surface 136 to be activated with hydroxyl bonds. In a preferred embodiment, bonding between the first oxide surface 126 and the second oxide surface 136 is achieved through formation of siloxane linkages. More advantageously, the activation of the oxide surfaces enables formation of siloxane linkages to occur at room temperature.

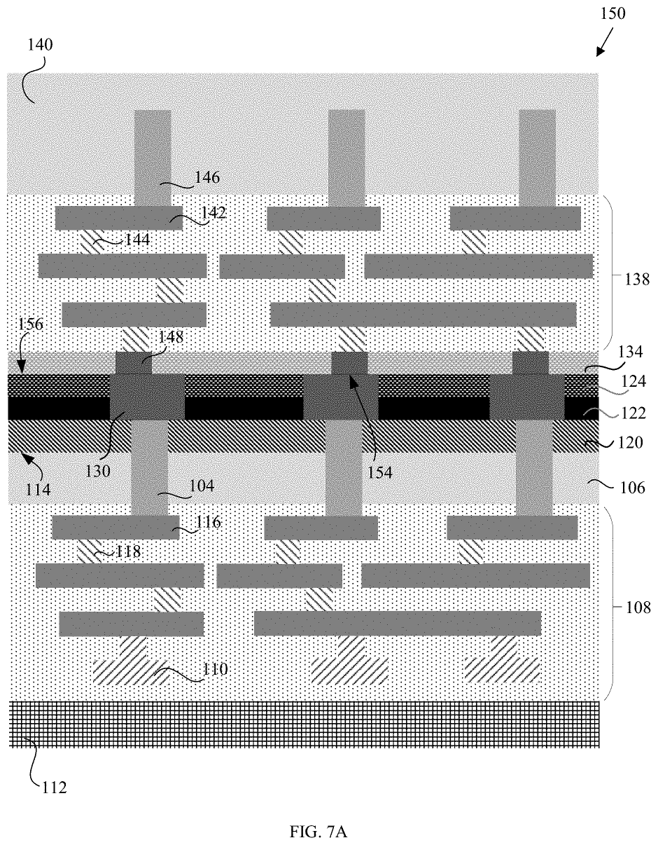

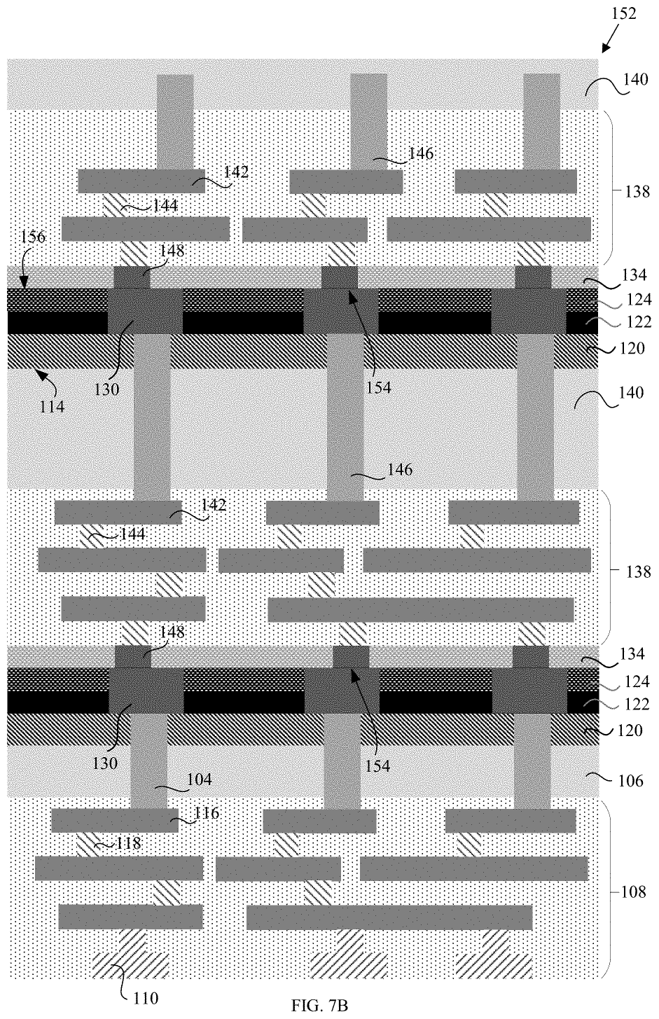

With reference to FIGS. 7A-7B in which like reference numerals refer to like features in FIG. 6 and at a subsequent fabrication stage, embodiments of a stacked semiconductor device are depicted. In FIG. 7A, there is shown a stacked semiconductor device 150 where copper connection points 154 are formed after annealing. Additionally, an oxide interfacial layer 156 is formed in between the first oxide layer 124 and the second oxide layer 134 after annealing. In FIG. 7B, there is shown a stacked semiconductor device 152 where a plurality of wafers are stacked on top of each other by repeating the bonding method as described herein. The plurality of wafers has copper connection points 154 after annealing. Additionally, an oxide interfacial layer 156 is formed in between the first oxide layer 124 and the second oxide layer 134 after annealing. In one embodiment, the sacrificial silicon layer 112 is removed by grinding to reveal the aluminum pads 110. As shown in FIGS. 7A-7B, the first silicon oxynitride layer 120 and the second silicon oxynitride layer 122 are sandwiched between the first oxide layer 124 and either the first substrate 106 or the second substrate 140. The stacked semiconductor devices described herein may be subsequently diced to form stacked chips.

The orientation of the first wafer 102 and the second wafer 132 depicted in FIG. 6 can be described as a “face-to-back” wafer bonding, and the stacked semiconductor devices depicted in FIG. 7A-7B are formed by the “face-to-back” wafer bonding orientation. It should be understood that at this point that a person skilled in the art would appreciate that the method described herein and the subsequently formed stacked semiconductor devices can be applied to a “face-to-face” wafer bonding.

In the context of “face-to-back” and “face-to-face” wafer bonding, the “back” side of a wafer is identified by the presence of the TSVs, redistribution layer and the silicon oxynitride layers, while the “face” side of the same wafer is identified by the presence of the dielectric layer and the FEOL components. Thus, the “face-to-back” wafer bonding has the dielectric layer and the FEOL components of a first wafer facing the TSVs, redistribution layer and the silicon oxynitride layers of an incoming second wafer. In a “face-to-face” bonding of two wafers (not shown), the dielectric layer and the FEOL components of a first wafer is facing the dielectric layer and the FEOL components of an incoming second wafer.

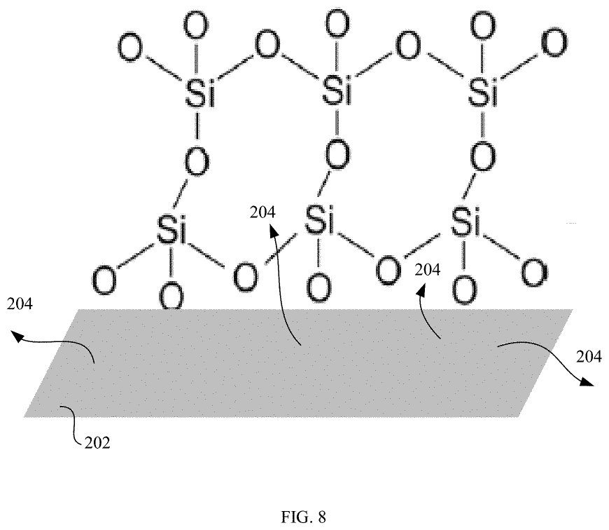

Referring to FIG. 8, there is shown a schematic diagram illustrating the mechanism in which hydrogen gases 204 permeate through a silicon oxynitride layer 202 positioned within a stacked semiconductor device. During the annealing process, hydrogen molecules may outgas from the dielectric layers formed by BEOL processes and escape through the silicon oxynitride layer 202, as shown in FIG. 8.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Furthermore, there is no intention to be bound by any theory presented in the preceding background or the detailed description.

Additionally, the various tasks and processes described herein may be incorporated into a more comprehensive procedure or process having additional functionality not described in detail herein. In particular, various processes in the manufacture of integrated circuits are well-known and so, in the interest of brevity, many conventional processes are only mentioned briefly herein or omitted entirely without providing the well-known process details.

As will be readily apparent to those skilled in the art upon a complete reading of the present application, the method disclosed herein may be employed in manufacturing a variety of different integrated circuit products, including, but not limited to, logic products, memory products, etc.

1. A method of manufacturing a stacked semiconductor device, the method comprising:
forming a hydrogen permeable barrier layer on a surface of a first wafer; and
forming a first oxide layer on the hydrogen permeable barrier layer;
forming a second oxide layer with conductive pads on a surface of a second wafer; and
bonding the first oxide layer with the second oxide layer, wherein the hydrogen permeable barrier layer is positioned between the first wafer and the second wafer.

2. The method of claim 1, wherein forming the hydrogen permeable barrier layer comprises forming a first silicon oxynitride layer on the surface of the first wafer.

3. The method of claim 2, wherein forming the hydrogen permeable barrier layer further comprises planarizing the first silicon oxynitride layer and forming a second silicon oxynitride layer on the first silicon oxynitride layer.

4. The method of claim 3, wherein
the first oxide layer is formed on the second silicon oxynitride layer.

5. The method of claim 4, further comprising performing an etch process on the first oxide layer and the second silicon oxynitride layer to form trenches positioned over the first silicon oxynitride layer, and filling the trenches with conductive materials.

6. The method of claim 4, wherein the bonding of the first oxide layer and the second oxide layer is performed by annealing to form the stacked semiconductor device.

7. The method of claim 6, wherein the bonding of the first oxide layer and second oxide layer further comprises treating the first and second oxide layers with plasma and water before annealing.

8. The method of claim 7, wherein the annealing occurs at a temperature between 260° C. and 400° C.

9. The method of claim 6, wherein bonding of the first oxide layer and second oxide layer further comprises aligning at least one of the conductive pads in the second oxide layer with at least one of the filled trenches in the first oxide layer.

10. A stacked semiconductor device comprising:
a first chip having a surface;
a hydrogen permeable barrier layer on the surface of the first chip;
a first oxide layer disposed on the hydrogen permeable barrier layer; and
a second oxide layer on a second chip, wherein -a the second oxide layer is bonded to the first oxide layer, and wherein the hydrogen permeable barrier layer is positioned between the first chip and the second chip.

11. The semiconductor device of claim 10, wherein the hydrogen permeable barrier layer comprises silicon oxynitride.

12. The semiconductor device of claim 11, wherein the hydrogen permeable barrier layer comprises a first silicon oxynitride layer and a second silicon oxynitride layer.

13. The semiconductor device of claim 12, wherein the first oxide layer is disposed on the second silicon oxynitride layer.

14. The semiconductor device of claim 13, wherein the second silicon oxynitride layer is positioned between the first oxide layer and the first silicon oxynitride layer.

15. The semiconductor device of claim 12, wherein the first silicon oxynitride layer has a thickness of 0.1 to 3 μm.

16. The semiconductor device of claim 12, wherein the second silicon oxynitride layer has a thickness of 0.09 to 0.2 μm.

17. The semiconductor device of claim 12, wherein the first and second silicon oxynitride layers have a refractive index in the range of 1.7 to 2.

18. The method of claim 1, wherein the hydrogen permeable barrier layer is formed on a first substrate of the first wafer.

19. The semiconductor device of claim 10, wherein the hydrogen permeable barrier layer is formed on a first substrate of the first chip.

20. The semiconductor device of claim 14, wherein the first silicon oxynitride layer is disposed on the surface of the first chip.
